(19) United States
(12) Patent Application Publication
(10) Pub. No.: US 2011/0318490 A1
(43) Pub. Date: Dec. 29, 2011

(54) METHOD FOR DEPOSITING A COATING

(75) Inventors: Lothar Schäfer, Meine (DE); Markus Höfer, Gardessen (DE); Tino Harig, Braunschweig (DE); Artur Laukart, Braunschweig (DE)

(73) Assignee: FRAUNHOFER GESELLSCHAFT ZUR FÖRDERUNG DER ANGEWANDTEN FORSCHUNG E.V., München (DE)

(21) Appl. No.: 13/254,558

(22) PCT Filed: Mar. 1, 2010
(86) PCT No.: PCT/EP2010/052561

§ 371 Date: Sep. 2, 2011

(30) Foreign Application Priority Data
Mar. 2, 2009 (DE) 10 2009 001 285.0
Mar. 30, 2009 (DE) 10 2009 015 545.7

(51) Int. Cl. C23C 16/44

(52) U.S. Cl. 427/255.394; 118/724; 427/255.28

(57) ABSTRACT

A coating apparatus and method for depositing a coating that contains at least one first element on a substrate by an activated vapor deposition, wherein the substrate is introduced into a gas atmosphere that contains at least the first element, and the gas atmosphere is activated by a heated activation element, wherein the first element is selected from among silicon, germanium, carbon, boron, or nitrogen, and the material of the activation element contains at least one metal and at least one second element, wherein the second element is selected from among silicon, boron, germanium, carbon, and/or nitrogen and is different from the first element.

The invention relates to a method for depositing a coating, which comprises at least one first element, on a substrate by means of an activated vapor deposition process, in which method the substrate is placed into a gas atmosphere which comprises at least the first element, and the gas atmosphere is activated by means of a heated activation element, wherein the first element is selected from silicon, germanium, carbon, boron or nitrogen.

M. Sommer, F. W. Smith, J. Mater. Res. Vol. 5, No. 11 discloses a coating apparatus and the use thereof. In said known method, a mixture of CH₄ and H₂ or C₂H₂ and H₂ as a precursor can be introduced via the gas supply device into the recipient. When the activation element has a temperature of over 1300 K, an activated gas phase is formed as a result of thermal and catalytic action of the surface of the activation element on the gas molecules, from which activated gas phase a coating can be formed on a substrate. For example, a diamond-comprising coating can be produced on the substrate by means of the described method.

A disadvantage of said known method is however that the precursor supplied via the gas supply device reacts with the material of the activation element. In this way, the activation element may be converted for example to tungsten silicide, tungsten carbide, tantalum carbide or a similar phase which is composed of at least one constituent of the precursor and at least one constituent of the activation element. Here, the conversion of the activation element takes place proceeding from the surface of the activation element into the interior thereof.

The phases formed during the conversion generally lead to changes in volume, are brittle and mechanically less loadable than the starting material, and often exhibit a changed electrical resistance. As a result, the activation element is often destroyed after only a few hours of operation. For example, the activation element may be used under mechanical preload in the recipient, and may break under the influence of said mechanical preload. Furthermore, the changed surface condition and the electrical resistance which changes over the service life cause a change in the activation rate of the precursor. As a result, the deposition rate and/or the quality of the built-up layer changes.

To prevent failure of the activation element under a mechanical preload, it is known to flush the clamping points with an inert gas. To keep the dynamics of the layer deposition constant, complex regulation of the electrical power consumption and/or of the temperature of the activation element is known.

It is accordingly the object of the invention to extend the service life of an activation element, and reduce the influence of the changing electrical resistance on the coating result, in a simple manner.

The object is achieved according to the invention by means of a method for depositing a coating, which comprises at least one first element, on a substrate by means of an activated vapor deposition process, in which method the substrate is placed into a gas atmosphere which comprises at least the first element, and the gas atmosphere is activated by means of a heated activation element, wherein the first element is selected from silicon, germanium, carbon, boron or nitrogen, and the material of the activation element comprises at least one metal and at least one second element, wherein the second element is selected from silicon, boron, germanium, carbon and/or nitrogen and differs from the first element.

Furthermore, the object is achieved according to the invention by means of an activation element (24) comprising: at least one first metal and at least one second metal which are selected from the group comprising Ti, V, Cr, Zr, Nb, Mo, Hf, Ta, W, Re, Os, Ir and Pt, and at least one element selected from the group comprising C, Ge, B, Si and N.

It is proposed by the inventors that the activation element is composed of a compound formed from at least two elements. During the operation of such an activation element, the material of such an activation element may be changed at least in some spatial regions as a result of the reaction with the gaseous precursors introduced. Here, the precursors comprise at least one element from the groups 111a, IVa, Va and/or VIa. The changed activation element may for example comprise a material which opposes to a greater extent the further attack by the precursors used for the coating process. In other embodiments of the invention, the changed activation element may have a diffusion barrier by means of which the admission of gas molecules of the precursor to deeper material layers of the activation element is at least hindered if not prevented entirely. In this way, a chemical conversion of the activation element with the precursor is slowed or prevented and the service life of the activation is increased, as is desired.

In one embodiment of the invention, the at least two different chemical elements which form the material of the activation element may form at least one mixed crystal phase. Within the context of the present invention, a mixed crystal phase refers to a compound which is composed of at least two different chemical elements, wherein the atoms of at least one element are arranged in a crystal lattice. The atoms of the second element may be either embedded in interstitial sites or may replace an atom of the first element by substitution. Such a mixed crystal phase with metallic properties may also be an alloy. Similarly, mixed crystal phases may also be present as ternary or multi-component compounds.

In one embodiment of the invention, the material of the activation element comprises at least one intermediate phase. Within the context of the present invention, an intermediate phase is to be understood to mean a compound of at least two elements which crystallize in a crystal structure which differs from the crystal structure of the pure elemental phases of the constituents, wherein the concentrations of the constituents either assume a fixed ratio with respect to one another or are at most variable in a narrow range.

In a further embodiment, the material of the activation element comprises at least one pure elemental phase. Here, a pure elemental phase refers to an amorphous or crystalline phase which is formed substantially from a single chemical element.

The presence of a mixed crystal phase does not rule out the possible presence of an intermediate phase and/or of a pure elemental phase. The presence of an intermediate phase does not rule out the possible presence of a mixed crystal phase and/or of a pure elemental phase. The presence of a pure elemental phase does not rule out the possible presence of an intermediate phase and/or of a mixed crystal phase.

If different pure elemental phases and/or at least one mixed crystal phase and/or at least one intermediate phase are compriseed in an activation element, these may form a layered structure with geometrically defined boundary surfaces, or may form a phase mixture or a eutectic or a eutectoid phase. Inevitable impurities may also be compriseed therein. Depending on the base material and manufacturing process used, these generally make up less than 1.5 percent by weight of the total mass. In some embodiments of the invention, less than 0.1 percent by weight. In some embodiments of the invention, less than 0.01 percent by weight.

In one embodiment of the invention, the activation element is formed such that it can be heated in a simple manner, provides as large a surface area as possible for the activation of the gas phase, and has the longest service life possible. The activation element may for example be of plate-shaped design and heated by means of a heating resistor or electron impact heating. In further embodiments of the invention, the activation element may be tubular and integrated into the gas supply device such that the gas supply device introduces an activated gas phase into the recipient. In one embodiment, the activation element may be formed by at least one wire. In this way, simple and uniform heating is ensured by means of direct current flow and a large active surface area.

In one embodiment of the invention, the activation element may be formed by a filament wire. To manufacture a filament wire of said type, it is for example possible for a cylindrical base body composed of a ductile first pure elemental phase and/or of a mixed crystal phase and/or of at least one intermediate phase to be produced, which cylindrical basic body is provided with cavities or through bores. A second pure elemental phase and/or a mixed crystal phase and/or an intermediate phase can then be introduced into said cavities or through bores. Depending on the situation, the second phase may be introduced in powder form. A wire can then be drawn out of the cylindrical base body in a manner known per se, which wire includes filaments of the second phase. A phase conversion and/or a chemical conversion may optionally be carried out by means of a tempering step. Here, a powder substance may be sintered.

In some embodiments of the invention, the material of the activation element comprises at least two different metals, wherein one element makes up at least 20 atomic percent of the compound. In some embodiments, one element makes up more than 40 atomic percent of the compound. In some embodiments, a compound may be used in which two elements make up in each case approximately 50 atomic percent. Such activation elements may for example comprise niobium and molybdenum, wherein the molybdenum fraction is approximately 20 percent by weight to approximately 51 percent by weight. In a further embodiment, the activation element may comprise tantalum and molybdenum, wherein the molybdenum fraction is approximately 10 percent by weight to approximately 35 percent by weight. In a further embodiment of the invention, the material of the activation element may comprise niobium and tungsten, wherein the tungsten fraction is approximately 30 percent by weight to approximately 67 percent by weight. Finally, the material of the activation element may comprise tantalum and tungsten, wherein the tungsten fraction is approximately 20 percent by weight to approximately 51 percent by weight.

Below, it is sought to explain the invention in more detail on the basis of figures and exemplary embodiments, without restriction of the general concept of the invention. In the figures:

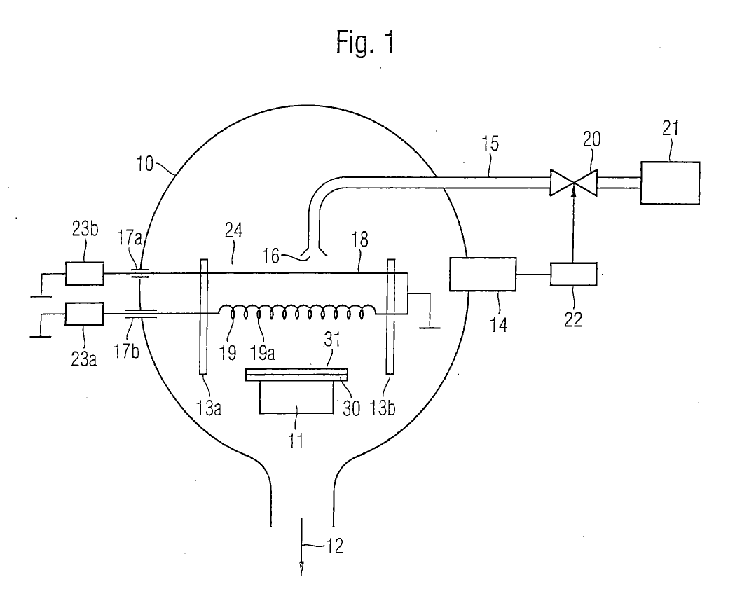

FIG. 1 shows the design of a coating apparatus proposed according to the invention.

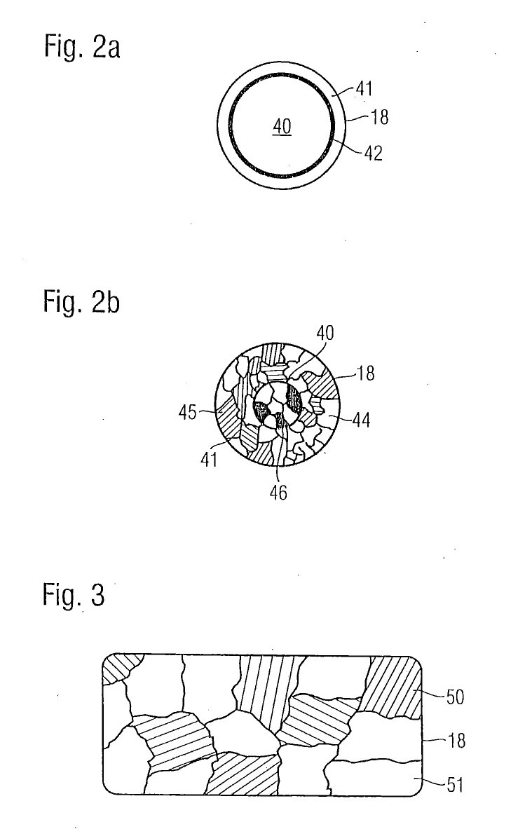

FIG. 2 shows the cross section through an activation element according to one embodiment of the present invention.

FIG. 3 shows the cross section through an activation element according to a further embodiment of the invention.

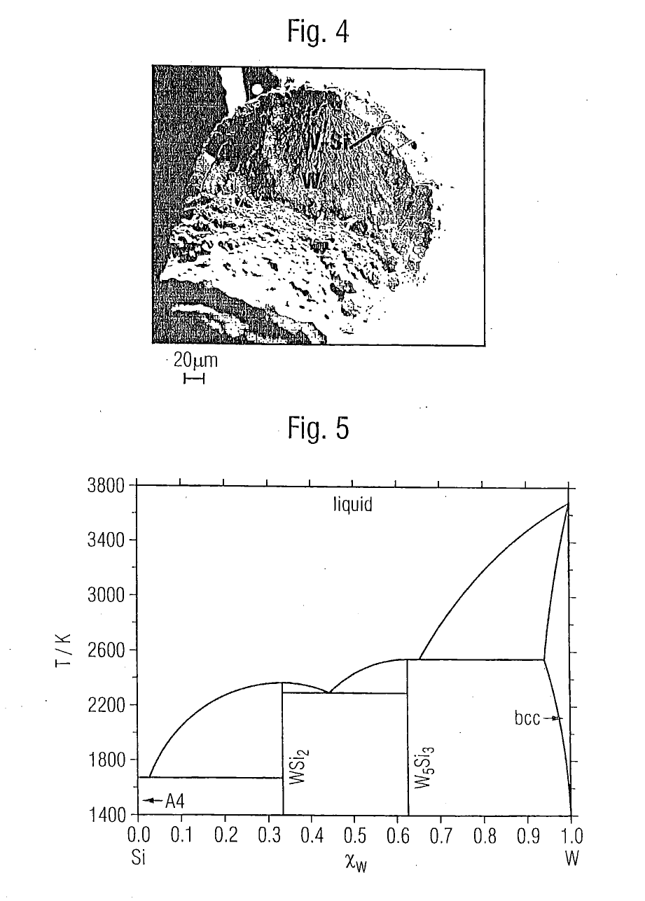

FIG. 4 shows an electron microscope image of a cross section through an activation element.

FIG. 5 shows, by way of example, a phase diagram of a material according to one exemplary embodiment of the present invention.

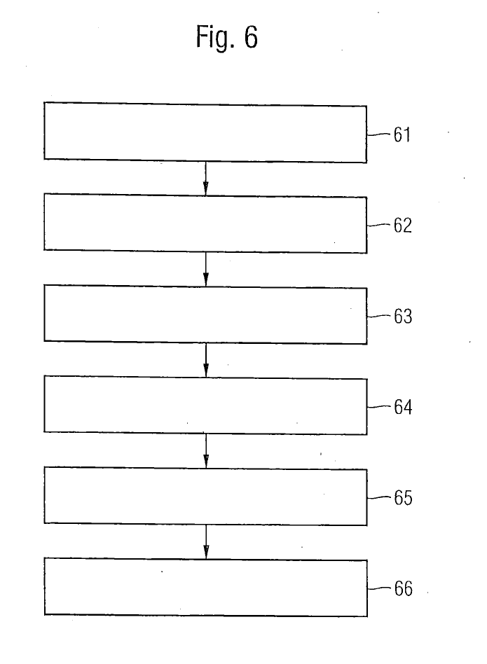

FIG. 6 shows a flow diagram of the method according to the invention.

FIG. 1 shows a cross section through a coating apparatus according to the invention. The coating apparatus comprises a recipient 1 which has a port 12 to which can be connected a vacuum pump such as is known per se. By means of the vacuum pump situated on the port 12, the recipient can be evacuated to a base pressure of less than 1×10⁻⁴ mbar, or less than 1×10⁻⁶ mbar or less than 1×10⁻⁷ mbar.

Various assemblies are arranged within the recipient. For example, the recipient 10 may have situated within it a substrate holder 11 on which a substrate 30 to be coated can be arranged. The substrate holder 11 may be designed to position the substrate 30 at a predefinable location within the recipient, to impart a preload to the substrate 30 and/or to heat or cool the substrate 30 to a predefinable temperature. The substrate holder 11 may furthermore be designed to hold a plurality of substrates. Furthermore, in some embodiments of the invention, a plurality of substrate holders may be provided. During operation of the coating apparatus, a coating 31 is deposited on the substrate 30.

Also illustrated is an activation element 24. In the illustrated exemplary embodiment, the activation element 24 comprises two wires 18 and 19. Here, the wire 18 has a stretched installation position. The wire 19 has a plurality of windings 19a by means of which the power requirement for heating can be reduced and/or the surface area of the wire 19 can be enlarged. The wires 18 and 19 may have a round cross section or any other desired cross-sectional shape, for example polygonal. Depending on the situation, only straight wires 18 or only wound wires 19 or a combination of both wires may be provided.

The wires 18 and/or 19 may comprise a compound formed from at least two elements selected from Si, C, N, B, Ti, V, Cr, Zr, Nb, Mo, Hf, Ta, W, Re, Os, Ir or Pt. The wires may comprise a plurality of different pure elemental phases and/or at least one mixed crystal phase and/or at least one intermediate phase. These may form a layered structure with geometrically defined boundary surfaces or a phase mixture and/or a eutectic and/or a eutectoid phase of the components compriseed therein.

Furthermore, the activation element 24 comprises two holding devices 13a and 13b by means of which a preload can be imparted to the wires 18 and 19. Depending on the desired coating process, the relative position of the activation element 24 with respect to the substrate 30 may be selected such that there is a direct line of sight between the activation element 24 and the substrate 30. In other embodiments of the invention, the substrate 30 may be arranged such that there is no direct line of sight to the activation element 24.

To initiate a layer deposition on the substrate 30, the activation elements 24 are brought to an elevated temperature which lies for example between 1300 K and approximately 3300 K. In the illustrated example, the heating of the wires 18 and 19 is realized by means of direct current flow, that is to say by resistance heating. For this purpose, in each case one end of the wires 18 and 19 is connected to a ground terminal. The end situated opposite the ground terminal in each case is guided out of the interior of the recipient 10, by means of a vacuum-tight electrical leadthrough 17a or 17b, to the outside. There, the connection of a power supply 23a and 23b assigned to the respective wire 18 and 19 is realized. Here, the power supply 23a and 23b may comprise regulating circuits which allow the respective temperature and/or the set current and/or the voltages applied to the wires 18 and 19 to be regulated to predefinable values.

The deposition of the layer 31 from the gas phase requires the presence of layer-forming substances or precursors. The provision of the precursors takes place via a gas supply device 15, 16, 20 and 21. Here, at least one gaseous precursor is situated in a gas reservoir 21, for example a pressure vessel or an evaporator. Said gas reservoir 21 is connected via a regulating valve 20 to a supply line 15. The supply line 15 ends within the recipient 10 at a gas outlet 16. The gas outlet 16 may be for example a freely ejecting pipe end, a nozzle or a gas distributor.

The pressure prevailing in the interior of the recipient 10 is monitored by means of a pressure measuring device 14. The pressure measuring device 14 may be for example a total pressure measuring unit, such as for example a Baratron, a Bayard-Alpert measurement tube or an inverted magnetron. The pressure measuring device 14 may alternatively also be a partial pressure measuring device, for example a quadrupole mass spectrometer.

The pressure recorded by the pressure measuring device 14 is transmitted to a regulating device 22. The regulating device 22 generates an actuating signal for the regulating valve 20 in order to regulate the pressure prevailing in the interior of the recipient 10, or the partial pressure of the precursor, to a predefinable setpoint value. If a plurality of different precursors are required, the gas reservoir 21 may comprise a correspondingly prepared gas mixture, or the different precursors are supplied via a multiplicity of gas supply devices 16, 15, 20 and 21 and associated measuring and regulating devices 14 and 22.

With the coating apparatus illustrated, coatings 31 of different type can be produced on the substrate 30. For example, CH₄ and H₂ may be used as a precursor in order to deposit a carbon-comprising coating on the substrate 30. Depending on the process parameters selected, the carbon-comprising coating may comprise crystalline diamond. Alternatively, the carbon-comprising coating may comprise diamond-like carbon (DLC), graphene or carbon nanotubes (CNT).

If a silicon-comprising gas such as for example silane (SiH₄) is used as a precursor, the coating may comprise amorphous (a-Si:H) or crystalline (c-Si:H) silicon. Layers composed of a plurality of components may be produced through the combination of different precursor gases or through the use of a multi-component precursor gas. For example, an SiN_{y} layer may be produced if silane and ammonia are used as process gases. An SiOₓN_{y} layer may be produced if silane, ammonia and oxygen are used as precursor gases. If trimethylsilane is used as a precursor gas, a silicon carbide layer may be produced.

In some embodiments of the invention, further gases may be present in addition to the precursor, for example as carrier gases or impurities. Impurities are in particular hydrocarbons, oxygen, nitrogen or water. Depending on the situation, these impurities may be detected in the layer 31.

FIG. 2 shows the cross section through a wire 18 which is part of the activation element 24. The cross section shows a core 40 with an cladding 41. Depending on the situation, a mixing zone 42 may be arranged between the core 40 and the cladding 41. In one embodiment of the invention, the core 40 comprises at least one metal selected from titanium, vanadium, chromium, zirconium, niobium, molybdenum, hafnium, tantalum, tungsten, rhenium, osmium, iridium or platinum. In some embodiments, the core may additionally comprise carbon, silicon, boron and/or nitrogen. The core 40 may comprise a binary, ternary or multi-component compound of the stated elements. Aside from these, depending on the situation, the core 40 comprises inevitable impurities such as for example aluminum, oxygen or further unspecified elements. The content of said impurities will however generally be less than 1.5% in relation to the weight.

If the core comprises at least two different chemical elements, these may form a mixed crystal phase and/or an intermediate phase and/or a pure elemental phase and/or a eutectic and/or a eutectoid phase. This results in a multiplicity of possible embodiments. By way of example, FIG. 2a shows the situation in which the core 40 comprises the first chemical element and the cladding 41 comprises the second chemical element. This results in a geometrically defined boundary surface between the two pure elemental phases. Alternatively, the core 40 may also be composed of an alloy of two different chemical elements and the cladding 41 may be formed by a pure elemental phase of a third chemical element.

FIG. 2b in turn shows another embodiment of the invention, in which the core 40 and the cladding 41 comprise in each case one mixed crystal phase 44 which coexist alongside further phases 45 and 46. Further exemplary embodiments of the invention may be combined on the basis of the illustrated principles.

According to one embodiment of the invention, the cladding 41 may also be formed by virtue of at least one element of the core 40 reacting with a gaseous element such as for example carbon, silicon, boron, nitrogen or germanium. In this way, the cladding 41 comprises for example a silicide, a carbide, a boride or a nitride. Since, with this form of manufacture, the gaseous substance diffuses into the interior of the wire 18 from the outside, a mixing zone 42 may form at the transition of the cladding 41 to the core 40, in which mixing zone the concentration of the indiffused element decreases continuously until the pure material of the core 40 is reached. In this case, the core 40 may for example be composed of a pure elemental tungsten phase. In this way, when the wire 18 is annealed in a silicon-comprising atmosphere which comprises for example 0.5% to 100% silane, an cladding 41 is formed which comprises WSiₓ. The cladding 41 may in this case be approximately 10 μm to 100 μm thick. This corresponds to approximately 10 percent to approximately 50 percent of the cross section of the activation element, which may have a diameter or a thickness of approximately 0.1 mm to approximately 2 mm, in some embodiments 0.2 mm to 0.7 mm. The cladding 41 and/or the mixing zone 42 may act as a diffusion barrier against the infiltration of precursors, or may comprise such a diffusion barrier. An activation element obtained in this way may have the advantage over an activation element provided with a coating that the bond strength between the cladding 41 and the core in the event of large temperature differences is improved. Furthermore, an activation element of said type may be surrounded by an cladding 41 of uniform thickness.

The example presented above may also be generalized to the effect that the core comprises two or more elements. For example, the core may comprise tantalum and tungsten and the cladding may comprise TaSi_{y} and/or WSiₓ and/or (Ta, W)ₘSi₁₋ₘ.

An activation element which comprises or is composed of at least a silicide and/or a nitride may, in some embodiments of the invention, be used for the deposition of a coating which comprises carbon. An activation element which comprises or is composed of at least a carbide and/or a nitride may, in some embodiments of the invention, be used for the deposition of a coating which comprises silicon. If the activation element comprises at least two metals, these may have different reaction kinetics with respect to the precursor, such that the second metal is protected by the reaction of the first metal with the precursor.

FIG. 3 shows a further exemplary embodiment of a cross section of a wire 18 of an activation element 24. The cross section in FIG. 3 shows an approximately polygonal shape with rounded corners. The activation element according to FIG. 3 is composed of a compound of at least two elements from the group comprising silicon, titanium, vanadium, chromium, zirconium, niobium, molybdenum, hafnium, tantalum, tungsten, rhenium, osmium, iridium or platinum. Here, the material of the activation element comprises two phases 50 and 51 which do not mix completely. For example, the phase 51 may be an intermediate phase which coexists alongside a pure elemental phase 50. In a further exemplary embodiment of the invention, the phase 51 may be an intermediate phase which coexists alongside a mixed crystal phase 50. In a third exemplary embodiment of the invention, the phase 51 may be a mixed crystal phase which coexists alongside a pure elemental phase 50, or the phase 51 may be a first mixed crystal phase which coexists alongside a second mixed crystal phase 50.

During operation of the activation element in the presence of a precursor which comprises elements from the groups 111a, IVa, Va and/or VIa of the periodic table, the material of the activation element may undergo a conversion during which elements of the precursor are integrated therein. For example, WC, SiC, W₅Si₃, (W, Ta)₅Si₃ or a similar phase may be formed under these circumstances. Here, it may be provided that only certain spatial regions or certain areal regions of the cross section participate in the conversion, such that a section of the activation element remains which is sufficient to ensure the function thereof. For example, it may be provided that the phase 51 participates, and the phase 50 does not participate or participates to a lesser extent, in the conversion with the precursor. In other embodiments of the invention, partial regions of the activation element may serve as diffusion barriers. In this case, an cladding is formed which is composed of a phase which acts as a barrier and which slows or prevents the further access of precursors. In some embodiments of the invention, the precursor may comprise at least one first element and the diffusion barrier may comprise at least one second element which differs from the first element.

FIG. 4 shows an electron microscope image of the cross section through an activation element according to the invention. The image in FIG. 4 was obtained with an acceleration voltage of 20 kV and an aperture of 30 μm. The scale of the figure is indicated.

FIG. 4 shows a substantially round cross section of an activation element 18. The latter is composed of a core W which comprises substantially a pure elemental tungsten phase. Formed at the outside around the core is an cladding W—Si which is composed substantially of tungsten silicides. According to the invention, it was possible to demonstrate that said cladding prevents the indiffusion of carbon and therefore the carburization of the core W. The service life of the activation element illustrated in FIG. 4 in a carbon-comprising precursor such as C₂H₄ or CH₄ is therefore increased in relation to the prior art.

FIG. 5 shows a phase diagram of the elements tungsten and silicon. The temperature in Kelvin is plotted on the ordinate and the concentration in atomic percent is plotted on the abscissa. Illustrated at the far right of the diagram, therefore, is a pure elemental tungsten phase (tungsten content 100 atomic percent) which has a melting point of 3695 K and a body-centered cubic crystal lattice (bcc). Illustrated at the far left of the diagram is a pure elemental silicon phase (tungsten content 0 atomic percent) which has a melting point of 1683 K and which is crystallized in a diamond structure (face-centered cubic lattice with diatomic basis).

At fixed concentration values, specifically a tungsten content of approximately 0.33 and 0.62 atomic percent, intermediate phases are formed, specifically WSi₂ and W₅Si₃. These are characterized by a tetragonal crystal lattice and ceramic or intermetallic properties. Within the context of the present invention, an intermediate phase is to be understood to mean a phase which is formed from at least two elements and which forms a crystal structure which differs from the crystal structures of the starting elements. If the mixing ratio of silicon and tungsten deviates from the stated values, a phase mixture of an intermediate phase and/or of pure silicon or tungsten and/or of a eutectic forms, such that the cross section shown in FIG. 3 may form.

FIG. 6 shows a flow diagram of the method according to the invention. In a first method step 61, an activation element is provided which is composed of at least one metal or which comprises at least one metal, as already described above. If the activation element comprises more than one metal, these metals may be present in different phases, as has already been described in conjunction with FIGS. 2 and 3. The at least one activation element is inserted into a coating apparatus, for example the coating apparatus which has already been explained in more detail on the basis of FIG. 1.

In the second method step 62, the activation element is exposed to a gas phase which comprises at least one second element. In some embodiments, the second element may be selected from silicon, boron, germanium, carbon and/or nitrogen. It is proposed according to the invention that the second element is at least not the main constituent of the coating to be activated by means of the activation element during the later coating. In some embodiments, the second element may nominally not be comprised in the coating to be deposited and/or in the gas phase to be activated, other than in the form of inevitable impurities. In some embodiments, in the second method step 62, silicon, boron or nitrogen may be selected as a second element if a carbon-comprising coating is to be deposited by means of the activation element. In other embodiments of the invention in which a silicon-comprising coating is to be deposited with the activation element, the second element may be selected from carbon, boron or nitrogen. If the activation element comprises two different metals, the second method step 62 is optional and may also be omitted in some embodiments of the invention.

In the third method step 63, the activation element is brought to a predefinable temperature for a predefinable time which may be approximately 15 to approximately 60 minutes. The predefinable temperature may be approximately 1780 Kelvin to approximately 2780 Kelvin. The temperature increase has the effect that the second element from the gas phase at least partially reacts with the activation element. In this way, silicides, carbides, borides or nitrides may form in or on the activation element. If the activation element comprises two different metals, the third method step 63 is optional and may also be omitted in some embodiments of the invention.

In the fourth method step 64, the gas phase which comprises the second element is removed from the recipient. If, in some embodiments of the invention, the second and third method steps are not carried out, the fourth method step 64 is also omitted.

In the fifth method step 65, a substrate to be coated is introduced into the coating apparatus. The substrate may be a machine component such as a bearing shell, a gearwheel, a floating ring seal, a bearing ring, a rolling body, a milling tool or a drilling tool. In other embodiments of the invention, the substrate may be a planar substrate, for example a silicon wafer or a glass substrate.

In the sixth method step 66, in a manner known per se, a coating which comprises at least the first element is deposited on the substrate. On account of the pretreatment of the activation element in the method steps 62 and 63, it is possible here for the aging resistance or the service life of the activation element to be increased during the coating by the formation of a protective layer or a diffusion barrier. In one embodiment, in the case of the deposition of a carbon-comprising coating on the substrate, the formation of carbides on the activation element may be suppressed or prevented by the preceding formation of nitrides, borides or silicides in method step 63. In one embodiment, in the case of the deposition of a silicon-comprising coating on the substrate, the formation of silicides on the activation element may be suppressed or prevented by the preceding formation of nitrides, borides or carbides in method step 63. If the activation element is composed of two different metals, it is possible as a result of different reaction dynamics for protection for the activation element to be formed from at least one metal and at least one constituent of the precursor.

A person skilled in the art is self-evidently familiar with the fact that the invention is not restricted to the illustrated exemplary embodiments. In fact, when implementing the invention, modifications and changes may be made without any significant change to the invention itself. The above description should therefore be regarded not as restrictive but rather as explanatory. The claims below should be understood to mean that the stated features are present in at least one embodiment of the invention. This does not rule out the possible presence of further features.

1.-27. (canceled)

28. A coating apparatus, comprising
at least one evacuable recipient being adapted to receive a substrate,
a gas supply device being adapted to provide at least on precursor gas, and
at least one heatable activation element, comprising at least a first and a second chemical element, being selected from Ti, V, Cr, Zr, Nb, Mo, Hf, Ta, W, Re, Os, Ir or Pt, wherein
the activation element has the shape of a filament wire comprising at least one metallic core and a cladding, wherein the core comprises the first chemical element and the cladding comprises the second chemical element.

29. The coating apparatus according to claim 28, wherein the activation element comprises any of at least one mixed crystal phase or at least one intermediate phase or at least one pure elemental phase.

30. The coating apparatus according to claim 28, wherein the wire has a diameter of approximately 0.1 mm to approximately 2.0 mm.

31. The coating apparatus according to claim 30, wherein the wire has a diameter of approximately 0.2 mm to 1 mm.

32. The coating apparatus according to claim 28, wherein a mixing zone is formed between the core and the cladding, within which mixing zone the material of the cladding merges continuously into the material of the core.

33. The coating apparatus according to claim 28, wherein the activation element comprises niobium and molybdenum, wherein the molybdenum fraction is approximately 20 to approximately 51 percent by weight.

34. The coating apparatus according to claim 28, wherein the activation element comprises tantalum and molybdenum, wherein the molybdenum fraction is approximately 10 to approximately 35 percent by weight.

35. The coating apparatus according to claim 28, wherein the activation element comprises niobium and tungsten, wherein the tungsten fraction is approximately 30 to approximately 67 percent by weight.

36. The coating apparatus according to claim 28, wherein the activation element comprises tantalum and tungsten, wherein the tungsten fraction is approximately 20 to approximately 51 percent by weight.

37. A method for depositing a coating, which comprises at least one first element, on a substrate (30) by means of an activated vapor deposition process, in which method the substrate (30) is placed into a gas atmosphere which comprises at least the first element, and the gas atmosphere is activated by means of a heated activation element (24), wherein the first element is selected from silicon, germanium, carbon, boron or nitrogen, wherein the activation element comprises at least one metalic core and a cladding, wherein the material of the core comprises any of W, Ta, Mo or Nb and the cladding comprises at least the material of the core and a second chemical element, wherein the second element is selected from any of silicon, boron, germanium, carbon or nitrogen and differs from the first element.

38. The method according to claim 37, wherein the activation element is formed by virtue of the core being exposed, at a predefinable temperature for a predefinable time, to a gas atmosphere which comprises at least the second element, such that a compound of the metal with the second element is formed.

39. The method according to claim 37, wherein the predefinable temperature is selected from the range from 1780 K to 2780 K.

40. The method according to claim 37, wherein the gas atmosphere which comprises the at least one second element comprises between approximately 0.5% and approximately 100% SiH₄.

41. The method according to claim 37, wherein the pressure of the gas atmosphere which comprises the at least one second element is approximately 0.1 Pa to approximately 100 Pa.

42. The method according to claim 37, wherein the predefinable time is approximately 15 minutes to approximately 60 minutes.

43. The method according to claim 37, wherein the cladding has a thickness of approximately 10% to approximately 50% of the cross section of the activation element.

44. The method according to claim 37, wherein the cladding has a thickness of approximately 10 μm to approximately 300 μm.

45. The method according to claim 37, wherein a layer comprising diamond and/or graphene is deposited on the substrate

46. The method according to claim 37, wherein a layer comprising silicon is deposited on the substrate.

47. The method according to claim 37, wherein a layer comprising germanium is deposited on the substrate.
